(19) United States
(12) Patent Application Publication
(10) Pub. No.: US 2025/0096177 A1
(43) Pub. Date: Mar. 20, 2025

(54) DISPLAY MODULE COMPRISING MICRO LIGHT EMITTING DIODE

(71) Applicant: SAMSUNG ELECTRONICS CO, LTD, Suwon-si (KR)

(72) Inventors: Yoonsuk LEE, Suwon-si (KR); Eunhye KIM, Suwon-si (KR); Dongyeob LEE, Suwon-si (KR); Sangmoo PARK, Suwon-si (KR)

(73) Assignee: SAMSUNG ELECTRONICS CO, LTD., Suwon-si (KR)

(21) Appl. No.: 18/962,923

(22) Filed: Nov. 27, 2024

Related U.S. Application Data
(63) Continuation of application No. PCT/KR2023/004116, filed on Mar. 28, 2023.

(30) Foreign Application Priority Data
May 27, 2022 (KR) 10-2022-0065572
Jul. 21, 2022 (KR) 10-2022-0090557

(51) Int. Cl. H01L 23/00; H01L 25/075; H01L 25/16; H01L 33/62

(52) U.S. Cl. CPC H01L 24/16; H01L 24/05; H01L 24/13; H01L 24/81; H01L 25/0753; H10H 20/857; H01L 25/167; H01L 2224/0401; H01L 2224/05611; H01L 2224/05639; H01L 2224/05644; H01L 2224/05647; H01L 2224/05655; H01L 2224/05666; H01L 2224/13082; H01L 2224/13109; H01L 2224/13111; H01L 2224/13139; H01L 2224/13147; H01L 2224/16227; H01L 2224/16502; H01L 2224/81203; H01L 2224/81805

(57) ABSTRACT

A display module includes: a plurality of light emitting diodes; a substrate having a plurality of indium-tin oxide (ITO) electrodes disposed thereon, the plurality of ITO electrodes being connected to electrodes of the plurality of light emitting diodes; and an assembly configured to connect the electrodes of the plurality of light emitting diodes and the plurality of ITO, wherein the assembly comprises a silver (Ag) paste to be applied on the plurality of ITO electrodes, and the electrodes of the plurality of light emitting diodes and the plurality of ITO electrodes of the substrate may be bonded by eutectic bonding through the assembly during thermal compression bonding.

### CROSS REFERENCE TO RELATED APPLICATIONS

This application is a continuation of International Application No. PCT/KR2023/004116, filed on Mar. 28, 2023, which is based on and claims priority to Korean Patent Application No. 10-2022-0065572 filed on May 27, 2022 in the Korean Intellectual Property Office and Korean Patent Application No. 10-2022-0090557 filed on Jul. 21, 2022 in the Korean Intellectual Property Office, the disclosures of which are incorporated by reference herein in their entireties.

### BACKGROUND

### 1. Field

The present disclosure relates to a display module including micro light emitting diodes.

### 2. Description of the Related Art

A display panel includes a substrate on which a plurality of thin film transistors (TFTs) are provided, and a plurality of micro light emitting diodes mounted on the substrate.

The plurality of light emitting diodes may be inorganic light emitting diodes that emit lights by themselves. The plurality of light emitting diodes express various colors as they operate in pixel or sub-pixel units. Operations of each pixel or sub-pixel are controlled by the plurality of TFTs. Each light emitting diode emits various colors, e.g., red, green, and blue.

A plurality of light emitting diodes arranged on a wafer or a relay substrate may be transferred to a substrate by a pick and place transfer method, a stamping transfer method, or a laser transfer method.

### SUMMARY

Provided is a display module including a bonding structure between electrodes of micro light emitting diodes and indium-tin oxide (ITO) electrodes of a substrate such that the electrodes of micro light emitting diodes and indium-tin oxide (ITO) electrodes of a substrate may be smoothly connected.

According to an aspect of the disclosure, a display module may include: a plurality of light emitting diodes; a substrate having a plurality of indium-tin oxide (ITO) electrodes disposed thereon, the plurality of ITO electrodes being connected to electrodes of the plurality of light emitting diodes; and an assembly configured to connect the electrodes of the plurality of light emitting diodes and the plurality of ITO, wherein the assembly comprises a silver (Ag) paste to be applied on the plurality of ITO electrodes, and the electrodes of the plurality of light emitting diodes and the plurality of ITO electrodes of the substrate may be bonded by eutectic bonding through the assembly during thermal compression bonding.

The electrodes of the plurality of light emitting diodes may be gold (Au) or alloy including gold (Au).

The electrodes of the plurality of light emitting diodes may made of a nickel/gold (Ni/Au) alloy, a titanium/gold (Ti/Au) alloy, copper (Cu), a copper/nickel (Cu/Ni) alloy, or a tin/silver (Sn/Ag) alloy.

The assembly may further include a bonding bump comprising a tin-silver-copper/indium (SnAgCu/In) alloy. The bonding bump may be melted with the silver paste during the thermal compression bonding, and a mixture of the bonding bump and the silver paste constitute the assembly.

### BRIEF DESCRIPTION OF THE DRAWINGS

The following drawings attached to this specification illustrate embodiments of the present disclosure and help understand the technical idea of the present disclosure along with the description of the invention below. The present disclosure shall not be construed as limited to the matters stated in the drawings.

FIG. 1 is a block diagram illustrating a display device according to some embodiments of the disclosure.

FIG. 2 is a plan view illustrating a display module according to some embodiments of the disclosure.

FIG. 3 is a cross-sectional view schematically illustrating a connection structure of micro LEDs provided on a display module and a substrate according to some embodiments of the disclosure.

FIG. 4 is a diagram illustrating a state before electrodes of micro LEDs are bonded to ITO electrodes of a substrate.

FIG. 5 is a diagram illustrating an example wherein micro LEDs transferred to a substrate are thermally compressed by a pressurization member.

FIG. 6 is a diagram schematically illustrating a cross-section of a pixel provided on a display module according to some embodiments of the disclosure.

FIG. 7 is a diagram illustrating a state before electrodes of micro LEDs are bonded to ITO electrodes of a substrate according to some embodiments of the disclosure.

FIG. 8 is a diagram illustrating micro LEDs which are transferred to a substrate being thermally compressed by a pressurization member according to some embodiments of the disclosure.

### DETAILED DESCRIPTION

Hereinafter, various embodiments will be described in more detail with reference to the accompanying drawings. The embodiments described in this specification may be modified in various ways. Also, specific embodiments will be illustrated in drawings, and the embodiments will be described in detail in the detailed description. However, the specific embodiments disclosed in the accompanying drawings are for promoting easy understanding of various embodiments. Accordingly, the technical idea of the disclosure is not limited by the specific embodiments disclosed in the accompanying drawings, and the embodiments should be interpreted to include all equivalents or alternatives of the embodiments included in the ideas and the technical scopes of the disclosure.

Also, in the present disclosure, terms including ordinal numbers such as ‘the first’ and ‘the second’ may be used to describe various components, but these components are not limited by the aforementioned terms. The aforementioned terms are used only for the purpose of distinguishing one component from another component.

In addition, in the present disclosure, terms such as “include” and “have/has” should be construed as designating that there are such characteristics, numbers, steps, operations, elements, components, or a combination thereof described in the specification, but not as excluding in advance the existence or possibility of adding one or more of other characteristics, numbers, steps, operations, elements, components, or a combination thereof. Also, the description in the disclosure that an element is “coupled with/to” or “connected to” another element should be interpreted to mean that the one element may be directly coupled with/to or connected to the another element, but still another element may exist between the elements. In contrast, the description that one element is “directly coupled” or “directly connected” to another element can be interpreted to mean that still another element does not exist between the one element and the another element.

Further, in the present disclosure, the expression ‘identical’ not only means that two components perfectly coincide with each other, but also means that a difference to a degree in consideration of a processing tolerance range is included.

Other than the above, in describing the present disclosure, in case it is determined that detailed explanation of related known functions or features may unnecessarily confuse the gist of the disclosure, the detailed explanation will be abridged or omitted.

According to some embodiments of the disclosure, a display module may include a plurality of light emitting diodes for displaying images. The display module may include a flat display panel or a curved display panel.

According to some embodiments of the disclosure, the light emitting diodes included in the display module may be inorganic light emitting diodes having sizes of 100 μm or smaller. For example, the inorganic light emitting diodes may be micro LEDs or mini LEDs, but are not limited thereto. Inorganic light emitting diodes have better brightness and light emitting efficiency, and a longer lifespan than organic light emitting diodes (referred to as ‘OLEDs’ hereinafter). Inorganic light emitting diodes may be semiconductor chips that can emit lights by themselves in case power is supplied. Inorganic light emitting diodes have fast response speed, low power consumption, and high luminance. In case inorganic light emitting diodes are micro LEDs, they may have higher efficiency in converting electricity into photons than an LCD or OLEDs. For example, micro LEDs may have higher “brightness per watt” than an LCD or an OLED display. Accordingly, micro LEDs can exert identical brightness with about half the energy compared to LEDs or OLEDs of which sizes exceed 100 μm. Also, micro LEDs can implement a high resolution, excellent colors, contrast, and brightness, and thus they can express colors in a wide range correctly, and can implement a clear screen outdoors brighter than indoors. In addition, micro LEDs are strong against a burn-in phenomenon and generate little heat, and thus a long lifespan without distortion can be guaranteed.

According to some embodiments of the disclosure, a light emitting diode may be constituted in a form of a flip chip wherein anode and cathode electrodes are disposed on an opposite surface of a light emitting surface.

According to some embodiments of the disclosure, on a first substrate of a substrate (e.g., the front surface of the substrate), a thin film transistor TFT layer wherein thin film transistor circuitry is formed may be disposed. On a second surface of the substrate (e.g., the rear surface of the substrate), power supply circuitry supplying power to the TFT circuitry and a data driving driver, a gate driving driver, and a timing controller controlling each driving driver may be disposed. On the TFT layer of the substrate, a plurality of pixels may be arranged. Each pixel may be driven by the TFT circuitry.

According to some embodiments of the disclosure, the TFTs formed on the TFT layer may be low-temperature polycrystalline silicon (LTPS) TFTs, low-temperature polycrystalline oxide (LTPO) TFTs, or oxide TFTs.

According to some embodiments of the disclosure, the substrate may be a glass substrate, a substrate based on a synthetic resin having flexibility (e.g., polyimide (PI), polyethylene terephthalate (PET), polyethersulfone (PES), polyethylene naphthalate (PEN), polycarbonate (PC), etc.), or a ceramic substrate.

According to some embodiments of the disclosure, the TFT layer of the substrate may be formed integrally with the first surface of the substrate, or manufactured in a form of a separate film, and attached on the first surface of the substrate.

According to some embodiments of the disclosure, the first surface of the substrate may be divided into an active area and an inactive area. The active area may be an area occupied by the TFT layer in the entire area of the first surface of the substrate. The inactive area may be an area excluding the active area in the entire area of the first surface of the substrate.

According to some embodiments of the disclosure, the edge area of the substrate may be the outermost area of the substrate. For example, the edge area of the substrate may include an area corresponding to the side surface of the substrate, some areas of the first surface of the substrate respectively adjacent to the side surface, and some areas of the second surface of the substrate. In the edge area of the substrate, a plurality of side surface wirings that electrically connect the TFT circuitry existing on the first surface of the substrate and the driving circuitry existing on the second surface of the substrate may be disposed.

According to some embodiments of the disclosure, the substrate may be formed as a quadrangle type. For example, the substrate may be formed as a rectangle or a square.

According to some embodiments of the disclosure, the TFTs provided on the substrate may be implemented as, for example, oxide TFTs and Si TFTs (polysilicon, a-silicon), organic TFTs, graphene TFTs, etc. other than low-temperature polycrystalline silicon (LTPS) TFTs. For the TFTs, only P-type (or N-type) MOSFETs may be made in an Si wafer CMOS process and applied.

According to some embodiments of the disclosure, in the substrate included in the display module, a TFT layer wherein TFT circuitry is formed may be omitted. In this case, a plurality of micro integrated circuit (IC) chips performing the function of TFT circuitry may be mounted on the first surface of the substrate. In this case, the plurality of micro ICs may be electrically connected with the plurality of light emitting diodes arranged on the first surface of the substrate through wirings.

According to some embodiments of the disclosure, a driving method of the pixels of the display module may be an active matrix (AM) driving method or a passive matrix (PM) driving method.

According to some embodiments of the disclosure, the display module may be installed and applied on wearable devices, portable devices, handheld devices, and electronic products or electronic components which need various kinds of displays.

According to some embodiments of the disclosure, a plurality of display modules may be connected in a grid arrangement and form a display device such as a monitor for personal computers, a high resolution television (TV) and signage (or, digital signage), an electronic display, etc.

According to some embodiments of the disclosure, one pixel may include a plurality of light emitting diodes. In this case, one light emitting diode may be a sub-pixel. In the disclosure, one ‘light emitting diode,’ one ‘micro LED,’ and one ‘sub-pixel’ may be interchangeably used as the same meaning.

Hereinafter, some embodiments of the disclosure will be described in detail with reference to the accompanying drawings, such that a person having ordinary knowledge in the technical field to which the disclosure pertains can easily carry out the embodiment. However, some embodiments of the disclosure may be implemented in several different forms, and is not limited to some embodiments of the disclosure described herein. Also, in the drawings, parts that are not related to explanation of the disclosure were omitted, for explaining some embodiments of the disclosure clearly, and throughout the specification, similar components were designated by similar reference numerals.

Hereinafter, a display module and a display device including the same according to some embodiments of the disclosure will be described with reference to the drawings.

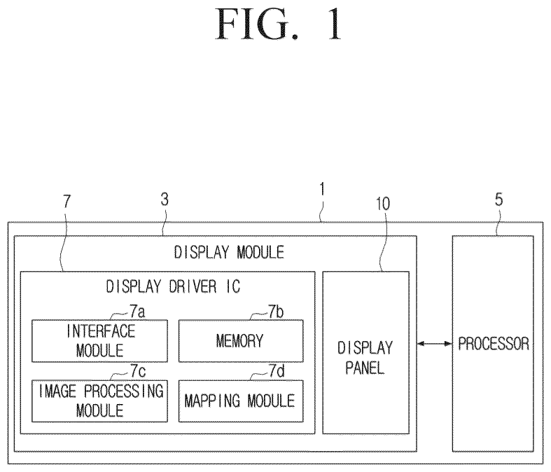

FIG. 1 is a block diagram illustrating a display device according to some embodiments of the disclosure.

Referring to FIG. 1, a display device 1 according to some embodiments of the disclosure may include a display module 3 and a processor 5.

The display module 3 according to some embodiments of the disclosure may display various images. Here, an image is a concept including a still image and/or a moving image. The display module 3 may display various images such as a broadcasting content, a multimedia content, etc. Also, the display module 3 may display a user interface and icons.

The display module 3 may include a display panel 10 and a display driver integrated circuit (IC) 7 for controlling the display panel 10.

The display driver IC 7 may include an interface module 7a, memory 7b (e.g.: buffer memory), an image processing module 7c, or a mapping module 7d. The display driver IC 7 may receive, for example, image data, or image information including an image control signal corresponding to an instruction for controlling the image data from another component of the display device 1 through the interface module 7a. For example, the image information may be received from the processor 5 (e.g.: a main processor (e.g.: an application processor) or a subsidiary processor (e.g.: a graphics processing device) operated independently from the function of the main processor).

The display driver IC 7 may receive at least a part of the received image information in the memory 7b in, for example, frame units. The image processing module 7c may, for example, perform pre-processing or post-processing (e.g.: adjustment of the resolution, the brightness, or the size) of at least a part of the image data based on the characteristics of the image data or the characteristics of the display panel 10. The mapping module 7d may generate a voltage value or a current value corresponding to the image data that was pre-processed or post-processed through the image processing module 7c. According to some embodiments, generation of a voltage value or a current value may be performed, for example, at least partially based on the attributes of the pixels of the display panel 10 (e.g.: arrangement of the pixels (an RGB stripe structure or an RGB pentile structure), or the sizes of each sub-pixel). At least some pixels of the display panel 10 may be driven, for example, at least partially based on the voltage value or the current value, and accordingly, visual information corresponding to the image data (e.g.: texts, images, or icons) may be displayed through the display panel 10.

The display driver IC 7 may transmit a driving signal (e.g.: a driver driving signal, a gate driving signal, etc.) to the display based on the image information received from the processor 5.

The display driver IC 7 may display an image based on an image signal received from the processor 5. As an example, the display driver IC 7 may display an image by generating a driving signal of the plurality of sub-pixels based on an image signal received from the processor 5, and controlling light emission of the plurality of sub-pixels based on the driving signal.

The display module 3 may further include touch circuitry. The touch circuitry may include a touch sensor and a touch sensor IC for controlling the same. The touch sensor IC may, for example, control the touch sensor for detecting a touch input or a hovering input for a designated location of the display panel 10. For example, the touch sensor IC may detect a touch input or a hovering input by measuring change of a signal (e.g.: a voltage, a light amount, a resistance, or a charge amount) for the designated location of the display panel 10. The touch sensor IC may provide information about the detected touch input or hovering input (e.g.: the location, the area, the pressure, or the time) to the processor 5. According to some embodiments, at least a part of the touch circuitry (e.g.: the touch sensor IC) may be included as a part of the display driver IC 7 or the display panel 10, or a part of another component arranged on the outside of the display module 3 (e.g.: the subsidiary processor).

The processor 5 may be implemented as a digital signal processor (DSP) processing digital image signals, a microprocessor, a graphics processing unit (GPU), an artificial intelligence (AI) processor, a neural processing unit (NPU), and a timing controller (TCON). However, the disclosure is not limited thereto, and the processor 5 may include one or more of a central processing unit (CPU), a micro controller unit (MCU), a micro processing unit (MPU), a controller, an application processor (AP), or a communication processor (CP), and an ARM processor, or may be defined by the terms. Also, the processor 5 may be implemented as a system on chip (SoC) having a processing algorithm stored therein or large scale integration (LSI), or implemented in the form of an application specific integrated circuit (ASIC) or a field programmable gate array (FPGA).

The processor 5 may control hardware or software components connected to the processor 5 by driving an operating system or an application program, and perform various kinds of data processing and operations. Also, the processor 5 may load an instruction or data received from at least one of the other components on volatile memory and process it, and store various kinds of data in non-volatile memory.

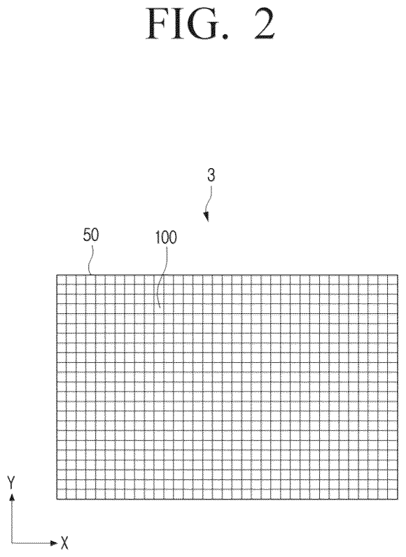

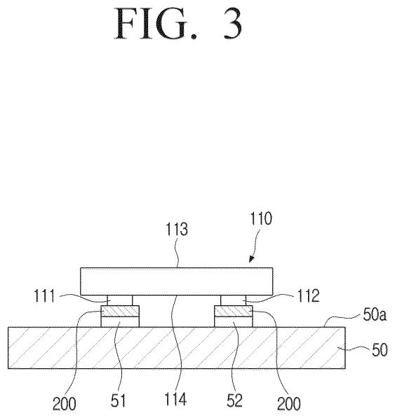

FIG. 2 is a plan view illustrating a display module according to some embodiments of the disclosure. FIG. 3 is a cross-sectional view schematically illustrating a connection structure of micro LEDs provided on a display module and a substrate according to some embodiments of the disclosure.

Referring to FIG. 2, the display module 3 may include a substrate 50, and a plurality of pixels 100 provided on the first surface of the substrate 50.

On the substrate 50, thin film transistor (TFT) circuitry electrically connected with the plurality of pixels 100 on the first surface may be provided.

The plurality of pixels 100 may respectively include at least three sub-pixels. A sub-pixel may be a micro LED which is an inorganic light emitting diode. Hereinafter, a sub-pixel will be referred to as a micro LED, for the convenience of explanation. Here, a micro LED may be defined as an LED of which size is 100 μm or smaller. The “size” may be a diameter in a given direction on a plane of a micro LED that was normally mounted. In an example, the given direction may be a horizontal direction or a vertical direction, and in another example, the given direction may be a direction having a maximum diameter on the plane.

The pixels 100 may include a first micro LED emitting a light of a red wavelength band, a second micro LED emitting a light of a green wavelength band, and a third micro LED emitting a light of a blue wavelength band.

Among the pixels 100, the first micro LED, the second micro LED, and the third micro LED may be disposed in pixel areas partitioned on the substrate 50. In areas not occupied by the first, second, and third micro LEDs among the pixel areas, a plurality of TFTs for driving the first, second, and third micro LEDs may be disposed.

The first, second, and third micro LEDs may be arranged in a line by a specific interval, but are not limited thereto. For example, the first, second, and third micro LEDs may be arranged in a shape of the character L, or arranged by a pentile RGBG method. The pentile RGBG method is a method of arranging the red, green, and blue sub-pixels in numbers in a ratio of 1:1:2 (R:G:B), by using a cognitive characteristic of a human of identifying a green color better than a blue color. The pentile RGBG method can heighten a yield rate and reduce a unit cost. The pentile RGBG method can implement a high resolution in a small screen.

The light emitting characteristic of the first micro LED may be identical to those of the second and third micro LEDs. A light emitted from the first micro LED may be a light having the same color as lights emitted from the second and third micro LEDs. In an example, all of the first to third micro LEDs may emit a blue light, a green light, or a red light. Accordingly, red, green, or blue monochromic lights may be emitted from the pixels 100, or lights wherein red, green, or blue colors are mixed may be emitted.

The display module 3 may be a touch screen combined with a touch sensor, a flexible display, a rollable display, and/or a three-dimensional display.

The TFTs provided on the substrate 50 may be amorphous silicon (a-Si) TFTs, low temperature polycrystalline silicon (LTPS) TFTs, low temperature polycrystalline oxide (LTPO) TFTs, hybrid oxide and polycrystalline silicon (HOP) TFTs, liquid crystalline polymer (LCP) TFTs, or organic TFTs (OTFTs).

Referring to FIG. 3, on one surface 50a of the substrate 50, a plurality of indium-tin oxide (ITO) electrodes 51, 52 to which the electrodes 111, 112 of the micro LEDs 110 are respectively connected may be provided. In this case, the ITO electrodes 51, 52 of the substrate 50 may respectively be connected electrically with the TFT circuitry of the TFT layer through via hole wirings.

The electrodes 111, 112 of the micro LEDs 110 may respectively be bonded with the corresponding ITO electrodes 51, 52 of the substrate 50 by eutectic bonding by an assembly 200.

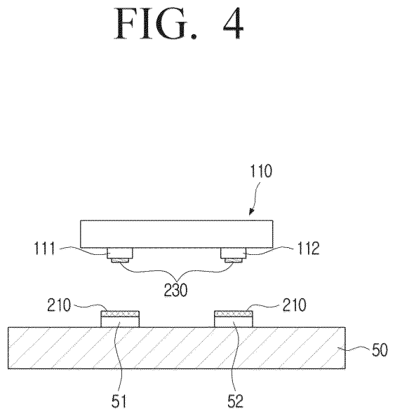

FIG. 4 is a diagram illustrating a state before electrodes of micro LEDs are bonded to ITO electrodes of a substrate.

Referring to FIG. 4, on each of the ITO electrodes 51, 52 of the substrate 50, a silver (Ag) paste 210 may be applied. The Ag paste 210 may modify the surfaces of the ITO electrodes 51, 52 of the substrate 50 to metallic surfaces.

The micro LED 110 may be in a form of a flip chip. For example, in the micro LED 110, the electrodes 111, 112 of the micro LED 110 may be disposed on the opposite surface 114 of the light emitting surface 113.

The electrodes 111, 112 of the micro LED 110 may made of, for example, a nickel/gold (Ni/Au) alloy, a titanium/gold (Ti/Au) alloy, copper (Cu), a copper/nickel (Cu/Ni) alloy, or a tin/silver (Sn/Ag) alloy.

On each of the electrodes 111, 112 of the micro LED 110, a bonding bump 230 may be formed. The bonding bump 230 may include tin-silver-copper/indium (SnAgCu/In).

The bonding bumps 230 are not limited to be formed on the electrodes 111, 112 of the micro LED 110. For example, the bonding bump 230 may be formed to be stacked on the Ag paste 210. In this case, the ITO electrodes 51, 52 of the substrate 50, the Ag paste 210, and the bonding bumps 230 may be sequentially stacked.

The micro LEDs 110 may be transferred from a wafer or a relay substrate to the substrate 50. For example, the micro LEDs 110 may be transferred from a wafer or a relay substrate to the substrate 50 by a laser transfer method, a pick and place transfer method, a stamping transfer method, a rollable transfer method, or a fluidic self-assembly transfer method.

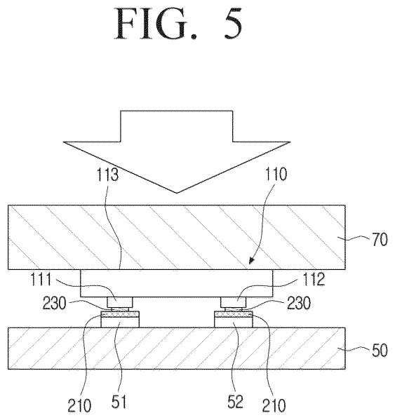

FIG. 5 is a diagram illustrating micro LEDs which are transferred to a substrate being thermally compressed by a pressurization member.

Referring to FIG. 5, the micro LEDs 110 transferred to the substrate 50 are pressurized by the pressurization member 70. In this case, heat of a high temperature may be applied to the substrate 50 and the micro LEDs 110.

When the micro LEDs 110 are thermally compressed, the silver (Ag) paste 210 and the bonding bumps 230 disposed between the ITO electrodes 51, 52 of the substrate 50 and the electrodes 111, 112 of the micro LEDs 110 may be melt by the heat of a high temperature.

The Ag paste 210 and the bonding bumps 230 may be formed as an assembly 200 (refer to FIG. 3) as they are fused with each other. The assembly 200 may be a medium that electrically and physically connects the ITO electrodes 51, 52 of the substrate 50 and the electrodes 111, 112 of the micro LEDs 110 with one another.

As the assembly 200 is melt by heat of a high temperature applied to the substrate during thermal compression bonding, the electrodes 111, 112 of the micro LEDs 110 and the ITO electrodes 51, 52 of the substrate 50 may be bonded by eutectic bonding.

As the Ag paste 210 is stacked on the surfaces of the ITO electrodes 51, 52 of the substrate 50, the ITO electrodes 51, 52 of the substrate 50 may be smoothly connected with the bonding bumps 230 during the thermal compression bonding. Like this, the Ag paste 210 promotes the bonding of the ITO electrodes 51, 52 of the substrate 50 with the bonding bumps 230.

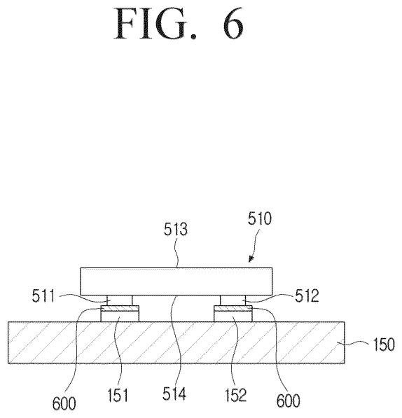

FIG. 6 is a diagram schematically illustrating a cross-section of a pixel provided on a display module according to some embodiments of the disclosure.

Referring to FIG. 6, on one surface 150a of the substrate 150, a plurality of ITO electrodes 151, 152 to which the electrodes 511, 512 of the micro LEDs 510 are respectively connected may be provided.

The electrodes 511, 512 of the micro LEDs 510 may respectively be bonded with the corresponding ITO electrodes 151, 152 of the substrate 150 by eutectic bonding by an assembly 600.

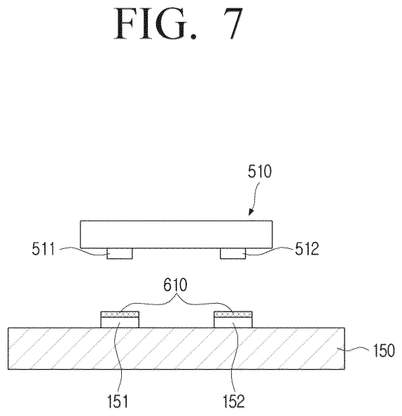

FIG. 7 is a diagram illustrating a state before electrodes of micro LEDs are bonded to ITO electrodes of a substrate.

Referring to FIG. 7, on each of the ITO electrodes 151, 152 of the substrate 150, a silver (Ag) paste 610 may be applied. The Ag paste 610 may modify the surfaces of the ITO electrodes 151, 152 to metallic surfaces.

The micro LED 510 may be in a form of a flip chip. For example, in the micro LED 510, the electrodes 511, 512 of the micro LED 510 may be disposed on the opposite surface 514 of the light emitting surface 513.

The electrodes 511, 512 of the micro LED 510 may be gold (Au) or alloy including gold (Au).

The micro LEDs 510 may be transferred from a wafer or a relay substrate to the substrate 150. For example, the micro LEDs 510 may be transferred from a wafer or a relay substrate to the substrate 150 by a laser transfer method, a pick and place transfer method, a stamping transfer method, a rollable transfer method, or a fluidic self-assembly transfer method.

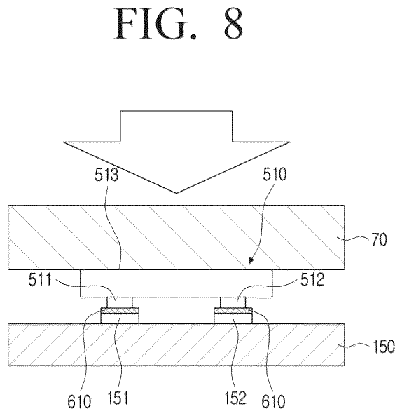

FIG. 8 is a diagram illustrating micro LEDs transferred to a substrate being thermally compressed by a pressurization member.

Referring to FIG. 8, the micro LEDs 510 transferred to the substrate 150 are pressurized by the pressurization member 70. In this case, heat of a high temperature may be applied to the substrate 150 and the micro LEDs 510.

When the micro LEDs 510 are thermally compressed, the silver (Ag) paste 210 may be melted and become an assembly 600 (refer to FIG. 6) that bonds the electrodes 511, 512 of the micro LEDs 510 with the ITO electrodes 151, 152 of the substrate 150.

As the assembly 600 is melted by heat of a high temperature applied to the substrate during thermal compression bonding, the electrodes 511, 512 of the micro LEDs 510 and the ITO electrodes 151, 152 of the substrate 150 may be bonded by eutectic bonding.

As the Ag paste 610 is stacked on the surfaces of the ITO electrodes 151, 152 of the substrate 150, electric and physical connection of the ITO electrodes 151, 152 of the substrate 150 with the electrodes 511, 512 of the micro LEDs 510 may be smoothly performed.

While the disclosure has been illustrated and described with reference to one or more embodiments, it will be understood that the one or more embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiments described herein may be used in conjunction with any other embodiments described herein.

What is claimed is:

1. A display module comprising:
a plurality of light emitting diodes;
a substrate having a plurality of indium-tin oxide (ITO) electrodes disposed thereon, the plurality of ITO electrodes being connected to electrodes of the plurality of light emitting diodes; and
an assembly configured to connect the electrodes of the plurality of light emitting diodes and the plurality of ITO electrodes,
wherein the assembly comprises a silver (Ag) paste to be applied on the plurality of ITO electrodes, and
wherein the electrodes of the plurality of light emitting diodes and the plurality of ITO electrodes are bonded by eutectic bonding through the assembly during thermal compression bonding.

2. The display module of claim 1, wherein the electrodes of the plurality of light emitting diodes are made of gold (Au) or an alloy including Au.

3. The display module of claim 1, wherein the electrodes of the plurality of light emitting diodes are made of a nickel/gold (Ni/Au) alloy, a titanium/gold (Ti/Au) alloy, copper (Cu), a copper/nickel (Cu/Ni) alloy, or a tin/silver (Sn/Ag) alloy.

4. The display module of claim 1, wherein the assembly further comprises a bonding bump comprising a tin-silver-copper/indium (SnAgCu/In) alloy, and
wherein the bonding bump is melted with the silver paste during the thermal compression bonding, and a mixture of the bonding bump and the silver paste constitutes the assembly.
